(19) United States
(12) Patent Application Publication
(10) Pub. No.: US 2015/0319863 A1
(43) Pub. Date: Nov. 5, 2015

(54) STRUCTURE AND METHOD FOR PREPARING A HOUSING TO ACCEPT A COMPONENT FOR AN EMBEDDED COMPONENT PRINTED CIRCUIT BOARD

(71) Applicants: Dhananjaya Turpuseema, Whitehouse Station, NJ (US); Thomas P. Warwick, Melbourne, FL (US); Thomas Smith, Easton, PA (US); James V. Russell, New Hope, PA (US)

(72) Inventors: Dhananjaya Turpuseema, Whitehouse Station, NJ (US); Thomas P. Warwick, Melbourne, FL (US); Thomas Smith, Easton, PA (US); James V. Russell, New Hope, PA (US)

(21) Appl. No.: 14/700,438

(22) Filed: Apr. 30, 2015

Related U.S. Application Data
(60) Provisional application No. 61/987,585, filed on May 2, 2014.

(51) Int. Cl. H05K 1/18; H05K 3/36; H05K 3/46; H05K 3/32; H05K 1/14; H05K 3/00

(52) U.S. Cl. CPC H05K 1/183; H05K 1/144; H05K 3/0094; H05K 3/4655; H05K 3/0026; H05K 3/321; H05K 3/4679; H05K 3/366; H05K 2201/032; H05K 2201/09509; H05K 2201/09572; H05K 2203/11; H05K 2201/09536; H05K 2201/09545; H05K 2201/0355; H05K 2201/042; H05K 2203/0485

(57) ABSTRACT

A method and electrical interconnect structure internal to a printed circuit board for the purposes of creating a reliable, high performing connection method between embedded component terminals, signal traces and or power/ground planes which may occupy the same vertical space as the embedded components, such as a capacitor or resistor. Further easing the assembly and reliability through the manufacturing process of said embedded component structures. In one structure castellated drilled, plated vias connect the trace or plane within the printed circuit board to the electrical terminals of the embedded component using a permanent and highly conductive attach material. In another structure, the trace or plane connect by selective side-wall plating, which surrounds the electrical terminal of the component. This structure also uses a permanent and highly conductive attach material to electrically connect the component terminal to the plated side-wall and in a final embodiment the terminals are connected through a conductive attach material through a via in the z axis to a conductive pad.

### BACKGROUND

1. Field

The present application relates to a structure and a method for preparing a housing to accept a component for an embedded printed circuit board and for an inter-level interconnect system. The present invention in particular provides for a structure for an electrical interconnect for an embedded printed circuit board or for an embedded multilayered printed circuit board. In particular the present invention provides a mechanism for improving printed circuit board embedded component performance, ease of manufacture and the use of vertical space required for embedding components.

2. The Related Prior Art

The prior art establishes the electrical benefit of the embedded component, as documented in multiple publications from the inventors and other sources. Embedded component technology places commercially available components, such as surface mount ceramic capacitors, surface mount resistors, and surface mount inductors inside the printed circuit board and in close proximity to connecting integrated circuits or other components. This provides greater circuit density and better electrical performance due to the shorter electrical lengths.

Prior art for embedded components require that the material surrounding the components be non-circuit layers. This creates three electrical and mechanical concerns:
1. No electrically conductive layers may reside in the embedded component vertical region, making this vertical region wasted space in a dense pc board.
2. On high layer count designs, with an extremely thick vertical stack, embedded components are often not a possibility due to vertical thickness limitations in manufacturing or in application.
3. The wasted vertical space drives large line widths for signal traces within the pc board that connect to the embedded component. This impedes routing and signal fidelity for escapes through a via field with a tight pitch (such as a large BGA device mounted above the embedded component).
4. The wasted vertical space forces supply planes and ground planes to be farther away from surface devices or forces the embedded component to be further away, thus making it less effective due to longer electrical length resulting in high supply loop inductance.
5. It is difficult to position the very small components in the proper orientation in an embedded structure and keep them in place during the construction of the printed circuit board.

It would be desirable to provide structures that resolve the limiting concerns of the prior art by allowing the connection of power planes, ground planes, and signal layers to co-reside with the embedded component and ease orientation of the components and to keep them in place through processing.

### SUMMARY

The present invention provides a structure and a method for an electrical interconnect structure for a single or multilayered printed circuit board to create a reliable high performance connection between signal traces and power/ground plane or planes that occupy the same vertical space as an embedded component such as a capacitor or a resistor. The present invention provides for a sub-lamination containing the embedded component that may have a number of metallic and non-conductive layers, as required by the application while easing the orientation and securing the component through the manufacturing process. This is a critical difference between this disclosure and prior art. The component terminals connect to these layers electrically through plating, micro-machining, and the use of conductive materials.

### BRIEF DESCRIPTION OF THE DRAWINGS

FIG. 1 is a first embodiment of the present invention for a single layer, two sided or subassembly of an embedded printed circuit board (PCB);

FIG. 2 is the first embodiment shown in FIG. 1 with lamination and cure of the embedded PCB or subassembly;

FIG. 3 is a second embodiment of the present invention with unclad dielectric carrier built-up on a single, or multilayer PCB;

FIG. 4 is a third embodiment of the present invention wherein internal or external layers of the carrier are connected to end points or terminals of embedded components of either a single or multilayer PCBs; and

FIG. 5 is a fourth embodiment of the present invention wherein instead of having internal or external layers connected to end points or terminals of embedded components of either a single or multilayer PCBs as in FIG. 4, adjacent vias are provided to bring the internal layer connections to the top or bottom of the dielectric material for solder, conductive paste or sinter paste bridging between the adjacent vias pad and the end point or terminals of the embedded component;

### DETAILED DESCRIPTION OF THE PREFERRED EMBODIMENTS

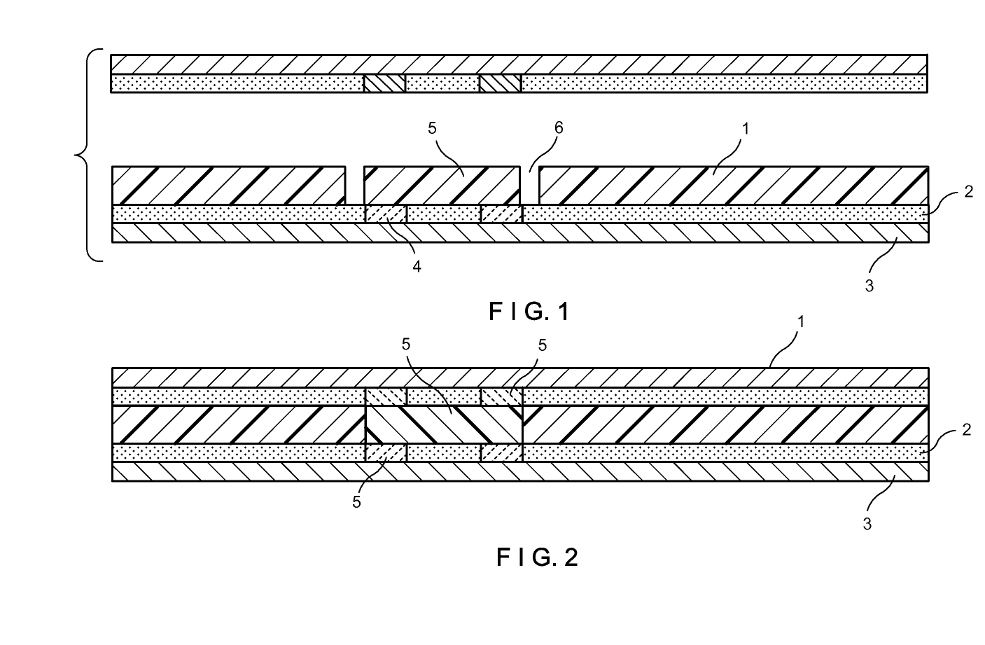

Referring now to the drawings of FIGS. 1-5, FIGS. 1-2 describe a first embodiment of the present invention in which a lamination adhesive or prepreg 2 is applied to a conductive foil 3 preferably a copper foil with the adhesive being partially cured as to provide adhesion to the foil but also allow it to flow again through additional lamination steps. This partial cure time, pressure and temperature will be dependent on the types of adhesive and vary from application to application but for purposes of a non-limiting example an Issola FR408 1080 prepreg requires approximately 125 pounds per square inch pressure, at 155 degrees Fahrenheit for 30 minutes. Vias 9 are formed through the adhesive 2 to expose the copper foil 3. It is understood that these vias may be formed with laser drilling, mechanically drilling, plasma etching, use of photo definable liquid dialectic or any other methods known in the art. The vias 9 are filled with conductive epoxy, sintering paste or solder paste 4. An unclad dielectric material 1 with cut outs 6 of an approximate shape, preferably slightly larger (1 to 3 mils), than the intended embedded component or components 5, with the proper orientation is/are tack bonded or laminated as shown in FIG. 2. The approximate shapes and sizes of the cut outs 6 for the present invention can vary and be any shape or preferred geometric shape including preferably but not limited to rectangular shapes. This partial cure time, pressure and temperature will be dependent on the types of adhesive and will vary with the type and thickness of the particular prepeg chosen based on the known manufacturing specifications for that chosen prepeg but by way of a non-limiting illustrative example the present invention can use but is not limited to using an Issola FR408 1080 prepreg that requires approximately 75 pounds per square inch pressure, at 150 degrees Fahrenheit for 14 minutes. The said cuts outs in the said unclad material as well as the said unclad material when bonded is/are oriented in order to locate the end points or terminals of the intended embedded components 5 to the vias 9 that are filled with paste 4.

The unclad dielectric material 1 with cutouts 6 are populated with components 5 using the cutouts 6 as a guide and a protective housing to keep the components 5 in place for the next operation. Next, another copper foil 3 is prepared similar to the first foil with conductive paste, sintering paste or solder 4 in the vias 9. It is aligned to the top of the unclad dielectric material 1 such that the vias 9 of the second foil are aligned to the end points or terminals of the opposite side of the embedded components 5 and the paste 4 is in contact with the terminals of the components 5. The second foil is then laminated to the top of the unclad material 1 through a curing process. This final cure time, temperature and pressure will be dependent on the types of adhesive but for purposes of a non-limiting example an Issola FR408 1080 prepreg requires approximately 200 PSI, at 376F for 90 minutes.

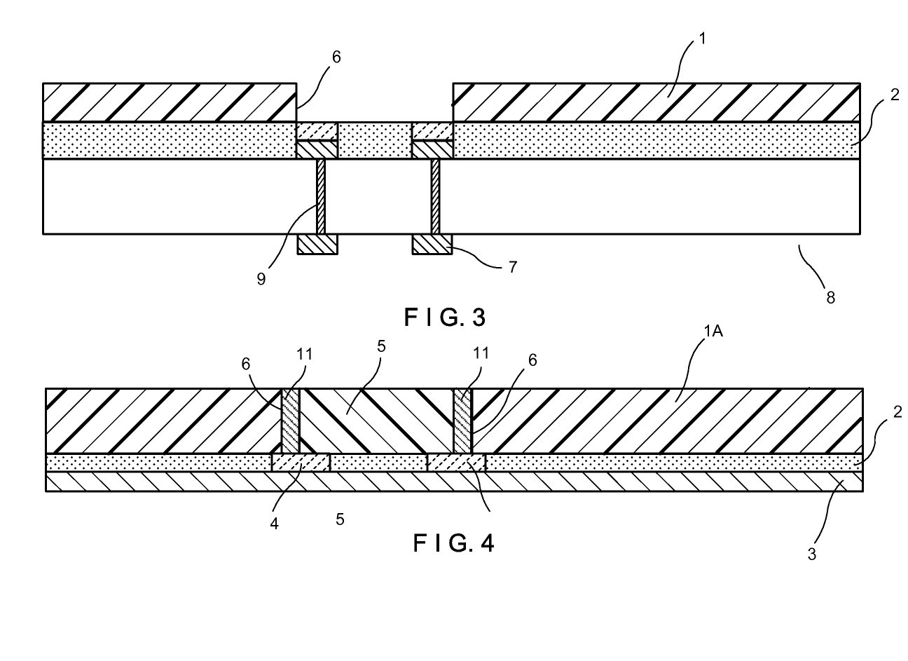

In another embodiment of the present invention as shown in FIG. 3 either or both of the foils described could be replaced with single or multilayered printed circuit boards or subassemblies. These subassemblies pads and or vias would be aligned to the end points or terminals of the embedded components 5 to provide electrical connection through the subassembly circuits and the embedded components 5.

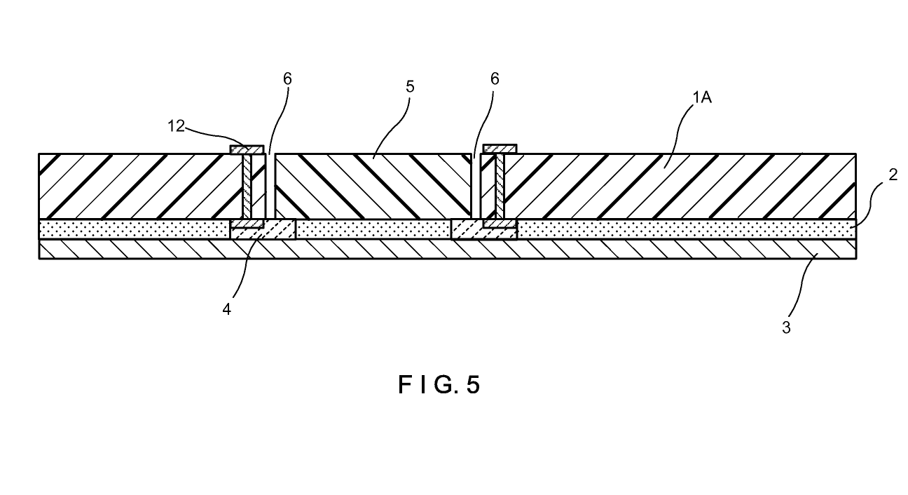

In a third embodiment of the present invention shown in FIG. 4 the unclad dielectric material 1 could be a single or multilayered printed circuit board with internal and/or external, power, ground and signal layers and optionally through blind or buried vias. Further, these internal and or external layers may be connected to the end points or terminals of the embedded components through selective metal plating the side walls 11 of the cutouts 6 that house the embedded components 5. Alternatively as shown in the embodiment of FIG. 5 adjacent vias 12 can be provided that bring the internal layer connections to the top or bottom of the dielectric material 1 for solder, conductive paste or sinter paste 4 bridging between the adjacent vias or pads 12 and the end point or terminals of the embedded components 5. In the structure of FIG. 4 however, unlike the alternative embodiment described below for FIG. 5, the cavities or cutouts 6 for the embedded components 5 are micro-machined prior to plating. The entire cut out 6 is thus plated and completes the normal printed circuit board process for the sub-lamination. This electrically shorts all connecting points for component 5 terminals together. Prior to component 5 insertion into the cavity 6, a micro-machining step cuts away electrically conductive metal plating between the terminal connections in the printed circuit board. This electrically isolates each pad appropriately. The commercially available component 5 is then inserted into the cavity 6 and pressed flat. The sub-lamination booklet is then completed with build-up layers—first non-conductive layers, followed by a metallic pad layer, and then heat pressed and cured. The non-conductive layer was first micro-machined with openings or vias, followed by a conductive attach material being placed into these openings or vias. The component 5 thus attaches to the plated side-walls 11 and/or to outer plating (metallic pads) during the curing process of the booklet/sub-lamination whereby the conductive attached material 4 (i.e. conductive epoxies, sintered pastes, solder paste) bridge the plated side wall and end points of the component 5. In the embodiment of FIG. 4, the single or multilayer PCB1A. aligns the embedded component or components to the paste or solder 4. The structure of the embodiment of FIG. 4 of the present invention uses a printed circuit board sub-lamination created to be approximately the same thickness or slightly thinner by ˜0.001 as the targeted commercially available component. FIG. 4 shows an alternate embodiment in which the structure is nearly identical to the process for the structure in FIG. 5. The sub-lamination contains any number of metallic and non-conductive layers, as required by the application. At the ends of the terminal locations of the proposed embedded component 5, drilled and plated through vias or blind vias exist. A precision micro-drilling mechanism cuts an appropriate opening the size and shape of the component 5 to be embedded. The micro-machining method may cut in approximately half or castellate the via, leaving one-half of it intact. Alternatively, the cut out end points can come into close proximity to the vias then the commercially available component 5 is inserted into the cavity 6 and pressed flat. The sub-lamination booklet is then completed with surface build-up layers—first non-conductive layers, followed by a metallic pad layer, and then heated, pressed and cured. The non-conductive layer was first micro-machined with openings, followed by a conductive attach material being placed into these openings. The embedded component 5 thus attaches to the cut out or castellated vias 6 or to the outer plating (metallic pads) during the curing process of the booklet/sub-lamination whereby the conductive adhesive (i.e. conductive epoxies, sintered pastes, solder paste) bridge the pads and or half vias and end points of the component 5.

While presently preferred embodiments have been described for purposes of the disclosure, numerous changes in the arrangement of method steps and apparatus parts can be made by those skilled in the art. Such changes are encompassed within the spirit of the invention as defined by the appended claims.

What is claimed:

1. A method for producing an electrical interconnect structure between a component terminal and a printed circuit board structure or subassembly, the steps comprising:
Forming a printed circuit board or subassembly by:
Laminating adhesive or prepreg to a first conductive foil only partially curing;
laser or mechanically drilling vias in said printed circuit board or said subassembly through the adhesive to expose the first copper foil;
filling the vias with conductive adhesive material;
tack bonding or tack laminating again not fully curing an unclad dielectric material with cut outs of an approximate shape to accommodate one or more components that are to be embedded within said printed circuit board or said subassembly; and
placing said one or more embedded components within said dielectric material cutouts thereby placing said end points of the one or more embedded component terminals in close proximity to said vias filled with said conductive adhesive material to provide electrical conductivity following a curing of said formed printed circuit board or said formed subassembly;
preparing a second foil, laminating adhesive or prepreg partially curing adhesive to said second conductive foil. Laser or mechanically drilling vias through said adhesive to expose the second copper foil and filling the vias with conductive adhesive substance;
aligning said second foil with top portion of said unclad dielectric materials so that said vias of said second foil are aligned with end points or terminals of opposite sides of said one or more embedded components;
laminating both first and second foils while finally curing the conductive adhesive substance.

2. The method according to claim 1 wherein said conductive adhesive material is conductive epoxy.

3. The method according to claim 1 wherein said conductive adhesive material is sintered paste.

4. The method according to claim 1 wherein said conductive adhesive material is solder paste

5. The method according to claim 1 wherein instead of bonding the unclad cut out material to the first foil, the cut outs are dimensioned to permit a friction fitting of said one or more components and the unclad material and the friction fitted one or more components are aligned to the first foil and the second foil and then finally cured.

6. An electrical interconnect structure between a component terminal and a printed circuit board structure or subassembly, comprising:
a printed circuit board or subassembly comprising:
adhesive or prepreg laminated to a first conductive foil only partially cured;
said printed circuit board or said subassembly laser or mechanically having drilled vias through the adhesive exposing the first copper foil;
said vias filled with conductive adhesive material;
an unclad dielectric material with cut outs of an approximate shape to accommodate one or more components that are to be embedded within said printed circuit board or said subassembly tack bonded or tack laminated again not fully cured; and
said one or more embedded components placed within said dielectric material cutouts so that said end points of the one or more embedded component terminals are placed in close proximity to said vias filled with said conductive adhesive material to provide electrical conductivity after curing said formed printed circuit board or said formed subassembly;
a second foil, laminating adhesive or prepreg formed by partially curing adhesive to said second conductive foil, and having laser or mechanically drilled vias through said adhesive to expose the second copper foil and said vias being filled with conductive adhesive substance;
said second foil being aligned with a top portion of said unclad dielectric materials so that said vias of said second foil are aligned with end points or terminals of opposite sides of said one or more embedded components;
both first and second foils being laminated while said conductive adhesive substance is being finally curried.

7. A method for producing an electrical interconnect structure between a component terminal and a printed circuit board structure or subassembly, the steps comprising:
forming a printed circuit board or subassembly by;
laminating adhesive or prepreg to a first printed circuit board or subassembly;
laser or mechanically drilling vias in said first printed circuit board or sub assembly through the adhesive to expose said first printed circuit board or subassemblies conductive circuit pads,
filling the vias with conductive adhesive material;
tack bonding or laminating an unclad dielectric material with cut outs of an approximate shape to accommodate one or more embedded components that are to be embedded within said formed printed circuit board or said formed subassembly; and
placing said one or more embedded components within said dielectric material cutouts;
forming either a second printed circuit board or subassembly or a foil by laminating adhesive or prepreg to said second printed circuit board or said subassembly or said foil, and laser or mechanically drilling vias through the adhesive to expose the said second printed circuit board or said subassembly or said foil and filling the vias with conductive adhesive material;
aligning said second printed circuit board or said second subassembly or said second foil with end points or terminals of opposite sides of said one or more embedded components, laminating to form said formed printed circuit board or said formed subassembly to provide an electrical interconnect structure.

8. The method according to claim 7 wherein said conductive adhesive material is a conductive epoxy.

9. The method according to claim 7 wherein said conductive adhesive material is sintered paste.

10. The method according to claim 7 wherein said conductive adhesive material is solder paste.

11. The method according to claim 7 wherein instead of bonding the unclad cut out material to the first foil, the cut outs are dimensioned to permit a friction fitting of said one or more components and the unclad material and the friction fitted one or more components are aligned to the first foil, or printed circuit board, or subassembly and the second foil, or printed circuit board or subassembly and then finally cured.

12. An electrical interconnect structure between a component terminal and a side wall of a printed circuit board or sub assembly, comprising:
a printed circuit board or subassembly formed by:
an adhesive or prepreg laminated to a first printed circuit board or subassembly;
said first printed circuit board or sub assembly having laser or mechanically drilling vias through the adhesive to expose said first printed circuit board or subassemblies conductive circuit pads,
said vias being filled with conductive adhesive material;
an unclad dielectric material with cut outs of an approximate shape to accommodate one or more embedded components that are to be embedded within said formed printed circuit board or said formed subassembly, said unclad dielectric material being tack bonded or laminated; and
said one or more embedded components being placed within said dielectric material cutouts;
either a second printed circuit board or subassembly or a foil being formed by an adhesive or prepreg laminated to said second printed circuit board or said subassembly or said foil, and vias that are laser or mechanically drilled through the adhesive exposing said second printed circuit board or said subassembly or said foil and said vias being filled with conductive adhesive material;
said second printed circuit board or said second subassembly or said second foil being aligned with end points or terminals of opposite sides of said one or more embedded components, laminated to form said formed printed circuit board or said formed subassembly to provide an electrical interconnect structure.

13. The structure according to claim 7 wherein said conductive adhesive material is a conductive epoxy.

14. The structure according to claim 7 wherein said conductive adhesive material is sintered paste.

15. The structure according to claim 7 wherein said conductive adhesive material is solder paste.

16. The structure according to claim 7 wherein instead of bonding the unclad cut out material to the first foil, the cut outs are dimensioned to permit a friction fitting of said one or more components and the unclad material and the friction fitted one or more components are aligned to the first foil, or first printed circuit board, or first subassembly and the second foil, or second printed circuit board or second subassembly and then finally cured.

17. A method for producing an electrical interconnect structure between a component terminal and a side wall of a single or multi-layered printed circuit board or subassembly, the steps comprising:
forming a single or multi-layered printed circuit subassembly by:
laminating adhesive or prepreg to a first conductive foil only partially curing;
laser or mechanically drilling vias in said printed circuit board or said subassembly through the adhesive to expose the first copper foil;
filling the vias with conductive adhesive material;
tack bonding or tack laminating again not fully curing an unclad dielectric material with cut outs of an approximate shape to accommodate one or more components that are to be embedded within said printed circuit board or said subassembly;
forming cutouts of an approximate shape to accommodate one or more components that are to be placed in said cutouts within said printed circuit board subassembly,
preparing a second foil, laminating adhesive or prepreg partially curing adhesive to said second conductive foil; laser or mechanically drilling vias through said adhesive to expose the second copper foil and filling the vias with conductive adhesive substance;
aligning said second foil with top portion of said unclad dielectric materials so that said vias of said second foil are aligned with end points or terminals of opposite sides of said one or more embedded components;
laminating both first and second foils while finally curing the conductive adhesive substance.
connecting said printed circuit board subassembly having internal or external power, and/or ground and/or signal layers to selective metal plating side walls of said formed cutouts;
placing said embedded components in the selectively plated cut outs with a friction fit and/or loosely housed, the said embedded components endpoints or terminals of one or more embedded components that are embedded within said cutouts are in close proximity and/or contacting the said selective side wall plating of the said cutouts; and
connecting the internal and/or external layers to the end points or terminals of the embedded components through conductive adhesive material bridging between said adjacent selective wall plating in the said cutouts and end points of terminals of said one or more embedded components.

18. The method according to claim 17 wherein said conductive adhesive material is conductive epoxy.

19. The method according to claim 17 wherein said conductive adhesive material is sintered paste.

20. The method according to claim 17 wherein said conductive adhesive material is solder paste.

21. The method according to claim 17 wherein the cut outs have no wall plating.

22. The method according to claim 17 wherein instead of bonding the single or multilayer printed circuit or subassembly cut outs to the first foil, the cut outs are dimensioned to permit a friction fitting of said one or more components and the single or multilayer printed circuit board or subassembly and the friction fitted one or more components are aligned to the first foil and the second foil and then finally cured.

23. An electrical interconnect structure between a component terminal and a side wall of a single or multi-layered printed circuit board or subassembly, the steps comprising:
a single or multi-layered printed circuit subassembly comprising:
an adhesive or prepreg laminated to a first conductive foil only partially curing;
vias laser or mechanically drilled in said printed circuit board or said subassembly through the adhesive to expose a first copper foil;
said vias being filled with conductive adhesive material;
an unclad dielectric material with cut outs of an approximate shape to accommodate one or more components that are to be embedded within said printed circuit board or said subassembly, said unclad dielectric material being tack bonded or tack laminated again not fully curing;
cutouts of an approximate shape for accommodating one or more components that are placed in said cutouts within said printed circuit board or subassembly,
a second foil being laminated with adhesive or prepreg partially curing, laser or mechanically drilled vias through said adhesive exposing the second foil and said vias being filled with conductive adhesive substance;
said second foil aligned with a top portion of said unclad dielectric material so that said vias of said second foil are aligned with end points or terminals of opposite sides of said one or more embedded components;
both first and second foils being laminated while finally curing the conductive adhesive substance;
said printed circuit board or said subassembly having internal or external power,
and/or ground and/or signal layers connected to selective metal plating side walls of said formed cutouts;
said embedded components placed in the selectively plated cut outs with a friction fit and/or loosely housed, said embedded components endpoints or terminals of one or more embedded components embedded within said cutouts in close proximity and/or contacting the said selective side wall plating of the said cutouts;
and the internal and or external layers to the end points or terminals of the embedded components being connected through conductive adhesive material bridging between said adjacent selective wall plating in the said cutouts and end points of terminals of said one or more embedded components.

24. The structure according to claim 22 wherein said single or multilayered printed circuit board has internal or external power, ground and signal layers connected through blind or buried vias adjacent to said cutouts.

25. The structure according to claim 24 wherein the said plated via is cut in half when said cutouts are formed providing said one or more components terminals with intimate connection or close proximity to the wall plating of half of the vias.

26. A method for producing an electrical interconnect structure between a component terminal and a side wall of a single or multi-layered printed circuit board or subassembly, the steps comprising:
forming a single or multi-layered printed circuit subassembly by:
laminating adhesive or prepreg to a first printed circuit board or subassembly;
laser or mechanically drilling vias in said first printed circuit board or sub assembly through the adhesive to expose said first printed circuit board or subassemblies conductive circuit pads,
filling the vias with conductive adhesive material;
tack bonding or laminating an unclad dielectric material with cut outs of an approximate shape to accommodate one or more embedded components that are to be embedded within said formed printed circuit board or said formed subassembly;
forming cutouts of an approximate shape to accommodate one or more components that are to be placed in said cutouts within said printed circuit board subassembly, connecting said printed circuit board subassembly having internal or external power, and/or ground and/or signal layers to selective metal plating side walls of said formed cutouts;
placing said embedded components in the selectively plated cut outs with a friction fit and/or loosely housed, the said embedded components endpoints or terminals of one or more embedded components that are embedded within said cutouts are in close proximity and/or contacting the said selective side wall plating of the said cutouts;
and connecting the internal and or external layers to the end points or terminals of the embedded components through conductive adhesive material bridging between said adjacent selective wall plating in the said cutouts and end points of terminals of said one or more embedded components, either a second printed circuit board or subassembly or a foil being formed by an adhesive or prepreg laminated to said second printed circuit board or said subassembly or said foil, and vias that are laser or mechanically drilled through the adhesive exposing said second printed circuit board or said subassembly or said foil and said vias being filled with conductive adhesive material;
said second printed circuit board or said second subassembly or said second foil being aligned with end points or terminals of opposite sides of said one or more embedded components, laminated to form said formed printed circuit board or said formed subassembly to provide an electrical interconnect structure.

27. The method according to claim 26 wherein said conductive adhesive material is conductive epoxy.

28. The method according to claim 26 wherein said conductive adhesive material is sintered paste.

29. The method according to claim 26 wherein said conductive adhesive material is solder paste.

30. The method according to claim 26 wherein the cut outs have no wall plating.

31. The method according to claim 26 wherein instead of bonding the single or multilayer printed circuit or subassembly cut outs to the first foil, the cut outs are dimensioned to permit a friction fitting of said one or more components and the single or multilayer printed circuit board or subassembly and the friction fitted one or more components are aligned to the first foil and the second foil and then finally cured.

32. An electrical interconnect structure between a component terminal and a side wall of a single or multi-layered printed circuit board or subassembly, comprising:
a single or multi-layered printed circuit subassembly comprising:
an adhesive or prepreg laminated to a first printed circuit board or subassembly; laser or mechanically drilled vias in said first printed circuit board or sub assembly through the adhesive exposing said first printed circuit board or subassemblies conductive circuit pads,
said vias filled with conductive adhesive material;
an unclad dielectric material with cut outs of an approximate shape to accommodate one or more embedded components that are to be embedded within said formed printed circuit board or said formed subassembly, said unclad dielectric material being tack bonded or laminated; cutouts of an approximate shape accommodating one or more components placed in said cutouts within said printed circuit board subassembly,
said printed circuit board subassembly having internal or external power, and/or ground and/or signal layers connected to selective metal plating side walls of said formed cutouts;
said embedded components placed in the selectively plated cut outs with a friction fit and/or loosely housed, said embedded components endpoints or terminals of one or more embedded components embedded within said cutouts in close proximity and/or contacting the said selective side wall plating of the said cutouts; and the internal and or external layers being connected to the end points or terminals of the embedded components through conductive adhesive material bridging between said adjacent selective wall plating in the said cutouts and end points of terminals of said one or more embedded components, either a second printed circuit board or subassembly or a foil formed by an adhesive or prepreg laminated to said second printed circuit board or said subassembly or said foil, and vias that are laser or mechanically drilled through the adhesive exposing said second printed circuit board or said subassembly or said foil and said vias being filled with conductive adhesive material;
said second printed circuit board or said second subassembly or said second foil being aligned with end points or terminals of opposite sides of said one or more embedded components, laminated to form said formed printed circuit board or said formed subassembly to provide an electrical interconnect structure.

33. The structure according to claim 32 wherein said single or multilayered printed circuit board has internal or external power, ground and signal layers connected through blind or buried vias adjacent to said cutouts.

34. The structure according to claim 33 wherein the said plated via is cut in half when said cutouts are formed providing said one or more components terminals with intimate connection or close proximity to the wall plating of half of the vias.
